(19) United States
(12) Patent Application Publication
(10) Pub. No.: US 2010/0248456 A1
(43) Pub. Date: Sep. 30, 2010

(54) Method of manufacturing semiconductor device

(75) Inventor: Keisuke Otsuka, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/659,890

(22) Filed: Mar. 24, 2010

(30) Foreign Application Priority Data
Mar. 25, 2009 (JP) P2009-074202

(51) Int. Cl. H01L 21/302; H01L 21/20; H01L 21/311

(52) U.S. Cl. 438/478; 438/689; 438/694; 257/E21.214; 257/E21.09; 257/E21.249

(57) ABSTRACT

A method of manufacturing a semiconductor device may include, but is not limited to the following processes. A first etching process is performed to etch a layer using a resist mask and a hard mask. The resist mask covers the hard mask. The hard mask covers the layer. Then, a second etching process is performed to etch the layer using the hard mask, substantially in the absence of the resist mask.

### BACKGROUND OF THE INVENTION

1. Field of the Invention

The present invention relates to a method of manufacturing a semiconductor device. Particularly, the present invention relates to a dry etching method using a two-layered mask including a resist mask and a hard mask.

Priority is claimed on Japanese Patent Application No. 2009-074202, filed Mar. 25, 2009, the content of which is incorporated herein by reference.

2. Description of the Related Art

To increase the precision of processing a target film using a mask including a photoresist layer, the thickness of the photoresist layer has to be reduced to increase the resolution. If the thickness of the photoresist layer is reduced too much, however, the photoresist layer becomes very thin during processing of the target film due to the selectivity between the photoresist layer and the target film, thereby making the processing of the target film difficult.

If the thickness of the photoresist layer has to be reduced, a known etching method can be used in which a hard mask layer is formed between the target film and the thin photoresist layer. Japanese Patent Laid-Open Publication No. 2000-311899 discloses two methods. A first method is a method of etching a target film using two layered mask including a resist mask and a hard mask while the resist mask used for patterning the hard mask remains. A second method is a method of etching a target film using only a hard mask.

Regarding the first method, the resist mask covering a surface of the hard mask prevents a reduction in thickness of the hard mask during etching. For this reason, the thickness of the hard mask can be further reduced compared to when a single layered mask, i.e., only the hard mask is used.

The resist mask covering the surface of the hard mask is simultaneously etched during etching the target film. In this case, decomposition of the resist mask causes generation of polymer. Then, the generated polymer attaches onto a side surface of the target film, which is the etching surface. The polymer attached onto the side surface (etching surface) of the target film can be used as a protection film when the side surface of the target film is etched (hereinafter, “side etching”), thereby preventing side etching of the target film.

Regarding a recent semiconductor-device manufacturing process, not only a single layered film or a multi-layered film made of the same material, but also a multi-layered film made of different materials is used as the target film. The aforementioned polymer has to be removed after the etching of the target film is complete.

However, a reaction product generated by the etching is occasionally included in the polymer depending on a material forming the target film. Depending on the type of the reaction product, it is occasionally difficult to remove the polymer including the reaction product from the etching surface of the target film even if a cleaning process is carried out after the etching.

For this reason, an etching technique is required which is adaptable to a target film included in a multi-layered structure, which causes generation of a reaction product during etching, and therefore is hard to remove. However, the two methods disclosed in the above related art cannot solve this problem.

### SUMMARY

In one embodiment, a method of manufacturing a semiconductor device may include, but is not limited to the following processes. A first etching process is performed to etch a layer using a resist mask and a hard mask. The resist mask covers the hard mask. The hard mask covers the layer. Then, a second etching process is performed to etch the layer using the hard mask, substantially in the absence of the resist mask.

In another embodiment, a method of manufacturing a semiconductor device may include, but is not limited to the following processes. A memory cell structure is formed. Then, a semiconductor layer is formed so as to cover the memory cell structure. Then, a metal layer is formed so as to cover the semiconductor layer. Then, a hard mask is formed so as to cover the metal layer. Then, a resist mask is formed so as to cover the hard mask. Then, a first etching process is performed to etch the semiconductor layer and the metal layer using the resist mask and the hard mask. Then, a second etching process is performed to etch the memory cell structure using the hard mask. The second etching process is performed in the absence of the resist mask.

In still another embodiment, a method of manufacturing a semiconductor device may include, but is not limited to the following processes. A first film is etched using a first mask and a second mask different from the first mask. The first mask covers the second mask. The second mask covers the first film. The first film covers a second film. At least a part of the first mask is etched by etching the first film. Then, a remaining portion of the first mask is removed if the remaining portion resides after etching the first film. Then, the second film is etched using the second mask.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 8 are cross-sectional views illustrating a capacitor formation process included in a method of manufacturing a semiconductor device according to a first embodiment of the present invention;

FIGS. 9 to 11 are cross-sectional views illustrating a mask-layer formation process included in the method according to the first embodiment;

FIG. 12 is a cross-sectional view illustrating a first etching process included in the method according to the first embodiment;

FIG. 13 is a cross-sectional view illustrating a photoresist-film removal process included in the method according to the first embodiment;

FIGS. 14 to 16 are cross-sectional views illustrating a second etching process included in the method according to the first embodiment; and

FIG. 17 is a cross-sectional view illustrating a cleaning process included in the method according to the first embodiment.

### DETAILED DESCRIPTION OF THE PREFERRED EMBODIMENTS

The present invention will now be described herein with reference to illustrative embodiments. The accompanying drawings show a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

According to a method of manufacturing a semiconductor device according to a first embodiment of the present invention, when selectively etching a target film using a mask layer including a hard mask film and a photoresist film, a first etching is carried out while the photoresist film is present. Then, a second etching is carried out while substantially no photoresist film is present.

The state where substantially no photoresist film is present indicates not only a literal meaning of no photoresist film being actually present, but also a very small amount of photoresist film which does not affect the second etching remains.

Since the first etching is carried out while the photoresist film is present, polymer generated by decomposition of the photoresist film attaches onto an etching surface of a film targeted for the first etching (hereinafter, “first film”). Thus, the first etching proceeds while the polymer prevents side etching of the first film.

Additionally, etching of the first film causes generation of a reaction product. The generation of the reaction product and the generation of polymer simultaneously occur during the first etching. Depending on a kind of the reaction product generated from the first film, it can be considered that the reaction product and the polymer combine each other, and consequently the polymer becomes hard to remove in a cleaning process.

For this reason, the first film to be etched in the first etching is preferably made of a material that causes generation of an etching product, which is hard to combine the polymer. For example, a material that causes generation of an etching product, which hardly remains on the etching surface, is preferable.

Since the second etching is carried out while substantially no photoresist film is present, polymer generated by decomposition of the photoresist film does not attach to the etching surface of a film targeted for the second etching (hereinafter, “second film”). For this reason, the second film does not cause generation of a protection film for preventing side etching.

On the other hand, the second etching also causes generation of an etching product from the second film. Since polymer is not generated as explained above, generation of the etching product and generation of polymer do not simultaneously occur during the second etching.

For this reason, a case where polymer becomes hard to remove due to generation of the etching product does not occur. Therefore, the second film is preferably made of a material causing generation of an etching product that does not affect the cleaning process. For example, even if a material causes generation of an etching product likely to remain on the etching surface, as long as the material can be easily removed in the cleaning process, the material can be used.

The first film is made of Al₂O₃, SiO₂, W, polysilicon, or the like. These materials cause generation of an etching product that hardly remains on the etching surface. Since Al₂O₃ is used as the hard mask film in the present embodiment, Al₂O₃ is not included in the first film.

The second film is made of TiN or the like. TiN causes generation of an etching product that is more likely to remain on the etching surface than the etching product generated by etching the first film.

An AlO/ZrO multi-layered film or a SiN film causes generation of en etching product that hardly remains on the etching surface, and therefore can be etched by the first etching. However, the AlO/ZrO multi-layered film or the SiN film is used as the second film in the present embodiment, and is etched by the second etching process.

Preferably, a film to be etched has a multi-layered structure including the first and second films, the first film being closer to the mask layer than the second film.

Hereinafter, a case where the method of the present embodiment is applied to a process of forming a capacity plate of DRAM (Dynamic Random Access Memory) is explained. The capacity-plate formation process schematically includes a capacitor formation process, a mask-layer formation process, a first etching process, a photoresist-film removal process, a second etching process, and a cleaning process. Hereinafter, each of the processes is specifically explained.

In the capacitor formation process, a transistor, a wiring, and the like, which are required for a semiconductor device, are formed over a semiconductor substrate 1, such as a silicon substrate, as shown in FIG. 1. Then, an inter-layer insulating film 2 is formed so as to cover the transistor, the wiring, and the like.

Then, contact holes 3 are formed in the inter-layer insulating film 2 using photolithography and dry etching to form contact plugs 4 made of tungsten (W). Then, the contact plugs 4 are connected to a drain region of the transistor.

Then, a cylinder stopper film 5 made of SiN, an inter-layer insulating film 6 made of a silicon oxide, and a support layer 7 made of SiN are sequentially deposited so as to cover the contact plugs 4 and the inter-layer insulating film 2.

The cylinder stopper film 5 serves as an etching stopper when the inter-layer insulating film 6 is etched. The inter-layer insulating film 6 is used for providing a cylinder hole, which is a basis for forming a lower electrode of a capacitor. The support layer 7 serves as a supporter for supporting the lower electrode.

When the semiconductor device of the present embodiment is used as a capacitor of DRAM elements, thicknesses of the inter-layer insulating film 6 and the support layer 7 are preferably approximately 2 μm and 100 nm, respectively.

Additionally, the inter-layer film 6 and the support layer 7 are preferably made of different materials. Particularly, an etching rate of the support layer 7 to an etchant when the inter-layer film 6 is wet etched is preferably smaller than that of the inter-layer film 6. Therefore, the inter-layer film 6 and the support layer 7 are preferably made of a silicon oxide film and a silicon nitride film, as explained above.

Then, the support layer 7, the inter-layer film 6, and the cylinder stopper film 5 are etched by photolithography and dry etching to form cylindrical holes 8. Then, a lower electrode film 9 is formed so as to cover an inner surface of the cylindrical holes 8 and the entire surface of the support layer 7.

The lower electrode film 9 is made of TiN, has a thickness of 7 nm, and will be a lower electrode of the capacitor. An upper surface of the contact plug 4 is exposed through a bottom of the cylindrical hole 8. The lower electrode film 9 is connected to the contact plug 4 at the bottom of the cylindrical hole 8.

For example, dry etching with a fluorine containing gas is carried out for etching the support layer 7 to form the cylindrical holes 8. Additionally, dry etching with a fluorine containing gas is carried out for etching the inter-layer film 6.

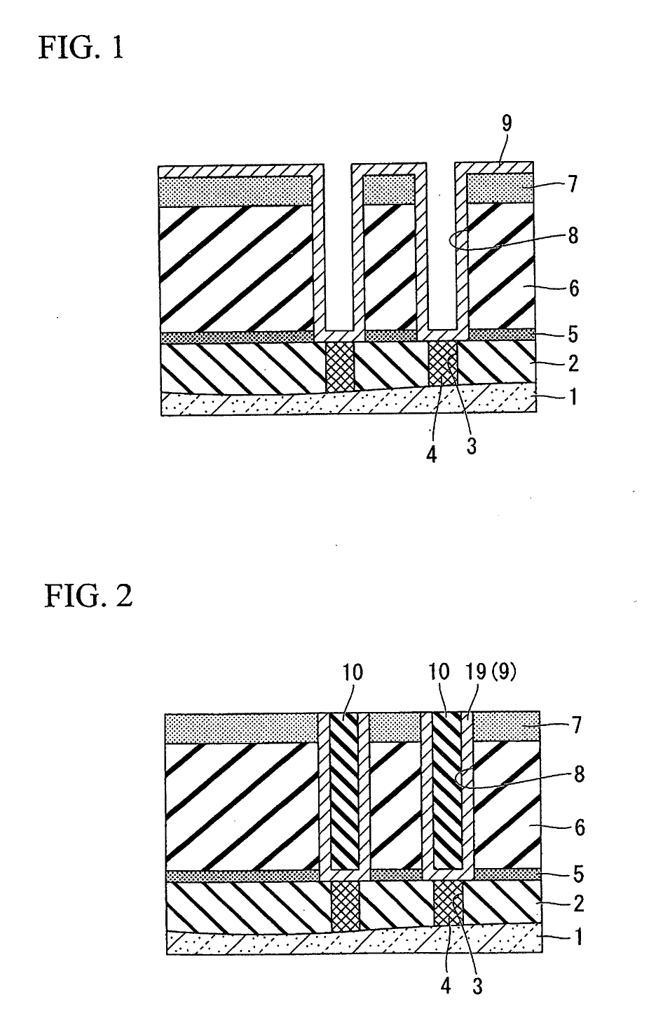

Then, an embedded film 10 made of silicon oxide is formed so as to fill the cylindrical hole 8, as shown in FIG. 2. Then, a lower electrode film 9 covering the upper surface of the support layer 7 is removed by CMP. The embedded film 10 prevents a slurry used for the CMP from dropping into the cylindrical hole 8.

After the lower electrode film 9 covering the upper surface of the support layer 7 is removed, the lower electrode film 9 remaining on the inner surface of the cylindrical hole 8 becomes a lower electrode (first electrode) 19 of a capacitor.

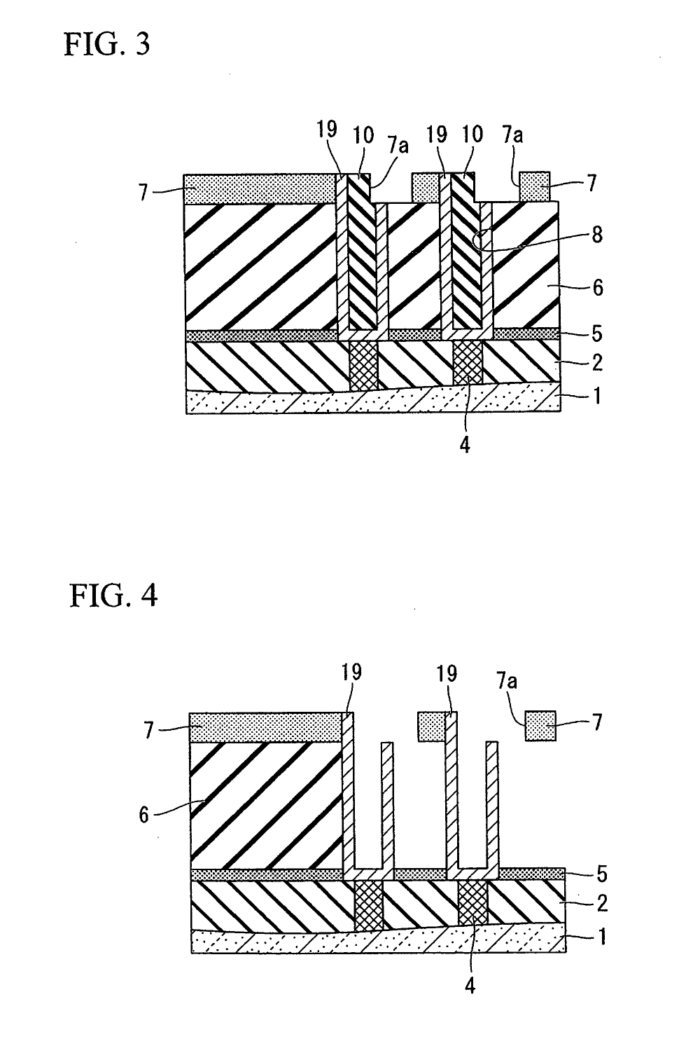

Then, the support layer 7 is partially etched by photolithography and dry etching to form holes 7a so that the holes 7a divide the support layer 7 into multiple portions, as shown in FIG. 3. Consequently, the inter-layer film 6 adjacent to the cylindrical hole 8 and the lower electrode 19 is partially exposed.

Then, an etching solution for wet etching is provided into the holes 7a to remove the embedded film 10 and the inter-layer film 6 by wet etching. The wet etching is carried out at a room temperature using concentrated hydrofluoric acid having a concentration of approximately 50%. In this case, the cylinder stopper film 5 serves as an etching stopper during the wet etching.

Consequently, the cylindrical lower electrode 19 having the bottom and empty space inside thereof is present. The support layer 7 connects adjacent lower electrodes 19. Specifically, an upper portion of the outer surface of the lower electrode 19 contacts with the support layer 7, and thereby the lower electrode 19 is mechanically supported by the support layer 7. The left region of the lower electrode 19 shown in FIG. 4 is a dummy region at the edge of the plate. Therefore, the hole 7a is not provided therein, and the inter-layer film 6 remains without being etched.

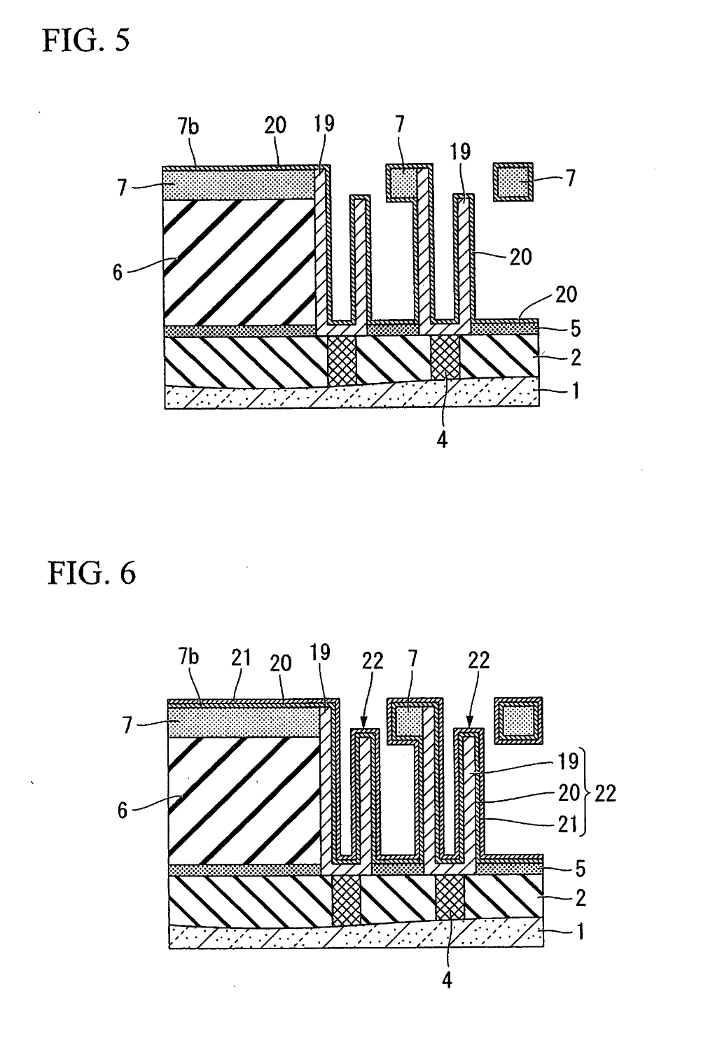

Then, a dielectric film 20 is formed by ALD (Atomic Layer Deposition) or the like so as to cover inner and outer surfaces of the lower electrode 19, an upper surface 7b of the support layer 7, and an upper surface of the cylinder stopper film 5, as shown in FIG. 5. The dielectric film 20 is made of a multi-layered film including aluminum oxide (AlO) and zirconium oxide (ZrO). A thickness of the dielectric film 20 is, for example, 7 nm.

Then, an upper electrode (second electrode, second film) 21 is formed by CVD so as to cover the dielectric film 20 and the support layer 7, as shown in FIG. 6. The upper electrode 21 is made of, for example, a single layered film including titanium nitride (TiN) having an excellent coverage. A thickness of the upper electrode 21 is, for example, 10 nm. Thus, a capacitor including the upper electrode (first electrode) 19, the dielectric film 20, and the upper electrode (second electrode) 21 is formed.

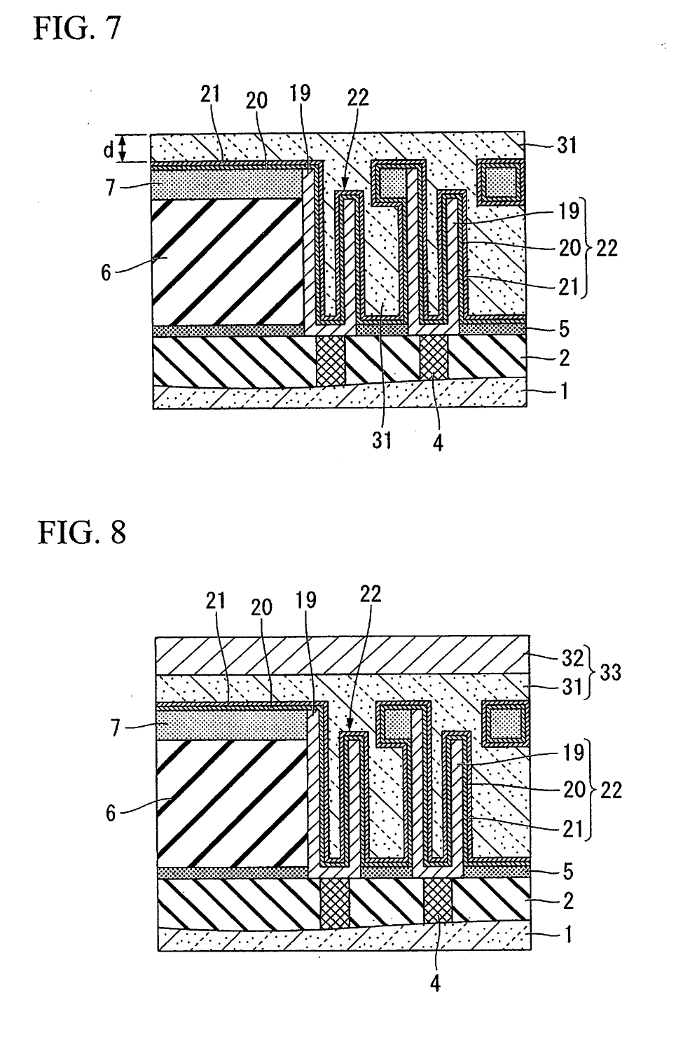

Then, an embedded underlying layer (semiconductor layer, first film) 31 is formed by CVD or the like so as to completely cover the upper electrode 21 over the support layer 7 and to have a thickness of approximately 150 nm from the upper surface of the support layer 7, as shown in FIG. 7. Since the embedded underlying layer 31 will become a part of the capacity plate layer, the embedded underlying layer 31 may be a semiconductor layer made of polysilicon or the like.

Then, a metal film (first film) 32, which will be a part of the capacity plate layer, is formed by spattering or the like over the embedded underlying layer 31, as shown in FIG. 8. The metal film 32 may be a single layered film made of tungsten or the like. A thickness of the metal film 32 is, for example, 100 nm. Thus, a capacity plate layer 33 including the embedded underlying layer (semiconductor layer) 31 and the metal layer 32 is formed.

Thus, the lower electrode 19 of the cell capacitor 22 is connected to a cell transistor (not shown) through the contact plug 4. The upper electrode 21 is connected to the capacity plate layer 33. The cell capacitor 22 including the dielectric film 20 and the upper electrode 21 covering both inner and outer surfaces of the lower electrode 19 has a crown shape. Thus, a memory cell mainly including the cell transistor and the cell capacitor 22 is formed over the semiconductor substrate 1.

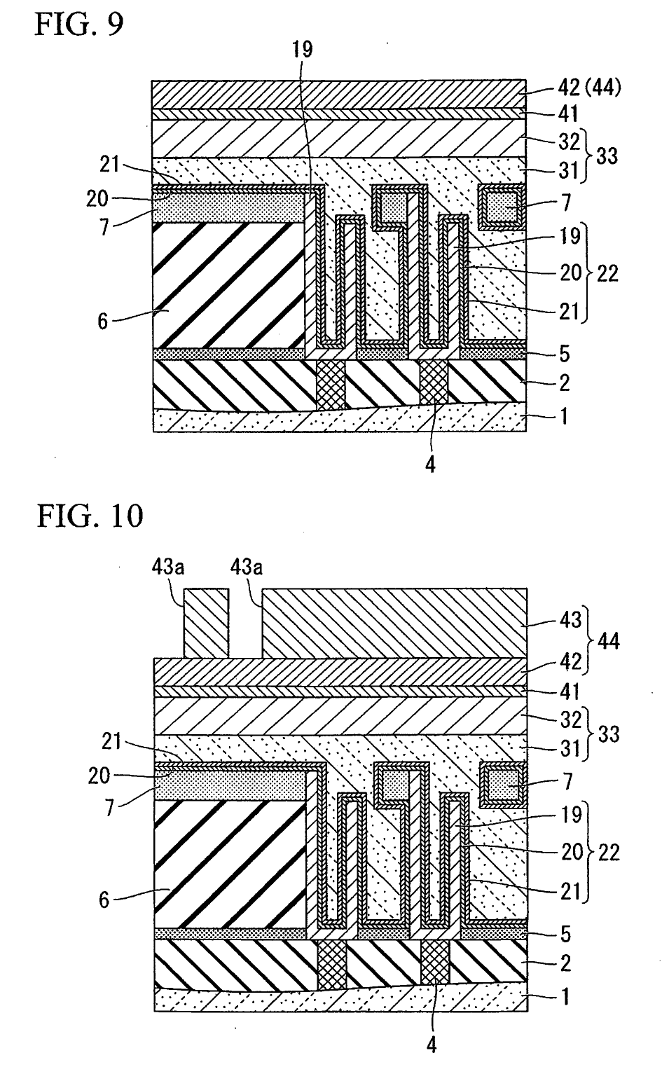

In the mask-layer formation process, a hard mask film 42 and a photoresist film 43 are sequentially deposited over the metal layer 32 to form a mask layer 44. Specifically, a peeling prevention film 41 for preventing a hard mask film from peeling is formed over the metal layer 32, as shown in FIG. 9. The peeling prevention film 41 is made of, for example, a silicon oxide film having a thickness of 50 nm.

Then, a hard mask film 42 is formed over the peeling prevention film 41. The hard mask film 42 is made of, for example, aluminum oxide (Al₂O₃) having a thickness of 35 nm. Then, a photoresist film 43 is formed over the hard mask film 42, as shown in FIG. 10. The photoresist film 43 is partially exposed and developed for patterning, and thereby holes 43a are formed.

In this case, a thickness of the photoresist film 43 is set to be identical to or greater than a value obtained by multiplying a thickness of each film to be etched by the etching selectivity of each film, and then summing the products. The etching selectivity of each film is selectively of each film to the photoresist film 43.

In the present embodiment, the hard mask film (35 nm in thickness) 42, the peeling prevention film (50 nm in thickness) 41, the metal layer (100 nm in thickness) 32, and the embedded underlying layer (150 nm in thickness) 31 are targeted for etching.

Assuming that the selectivity of each of these films to the photoresist film 43 is 1, the minimum thickness of the photoresist film 43 is 335 nm (35 nm+50 nm+100 nm+150 nm). In the present embodiment, extra 15 nm is further added to the minimum thickness, and therefore 350 nm is set to the thickness of the photoresist film 43.

In the etching process below, ICP-RIE (Inductively Coupled Plasma-Reactive Ion Etching) is carried out. The common conditions of the first etching process are that the source power is 1000 W, the high frequency power is 50 W to 200 W, the pressure is 5 mTorr to 20 mTorr, and the stage temperature is 20° C. to 40° C.

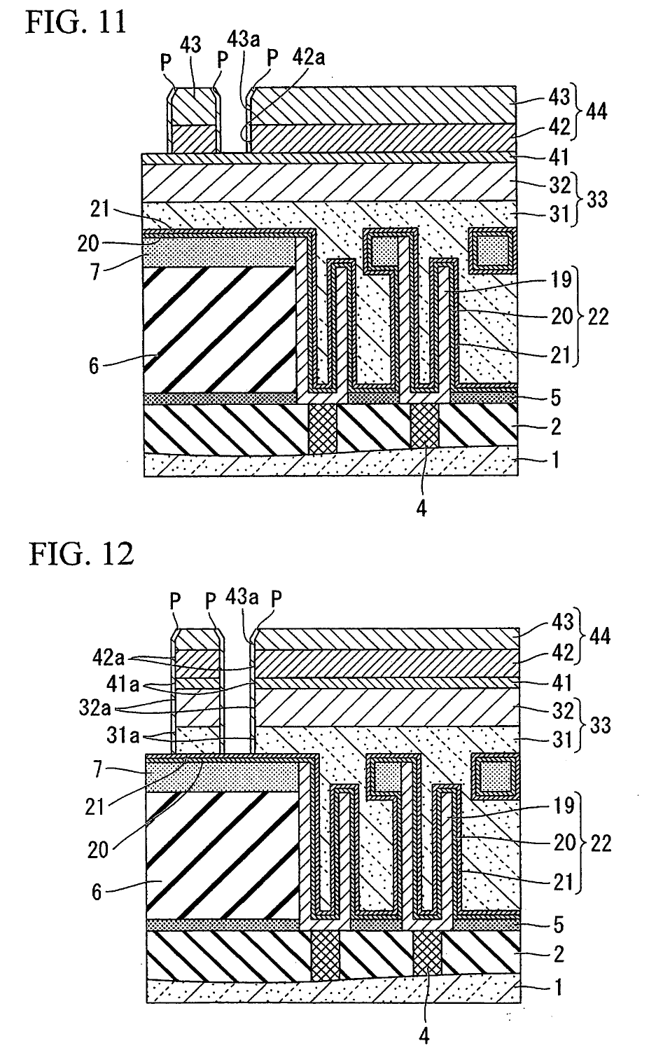

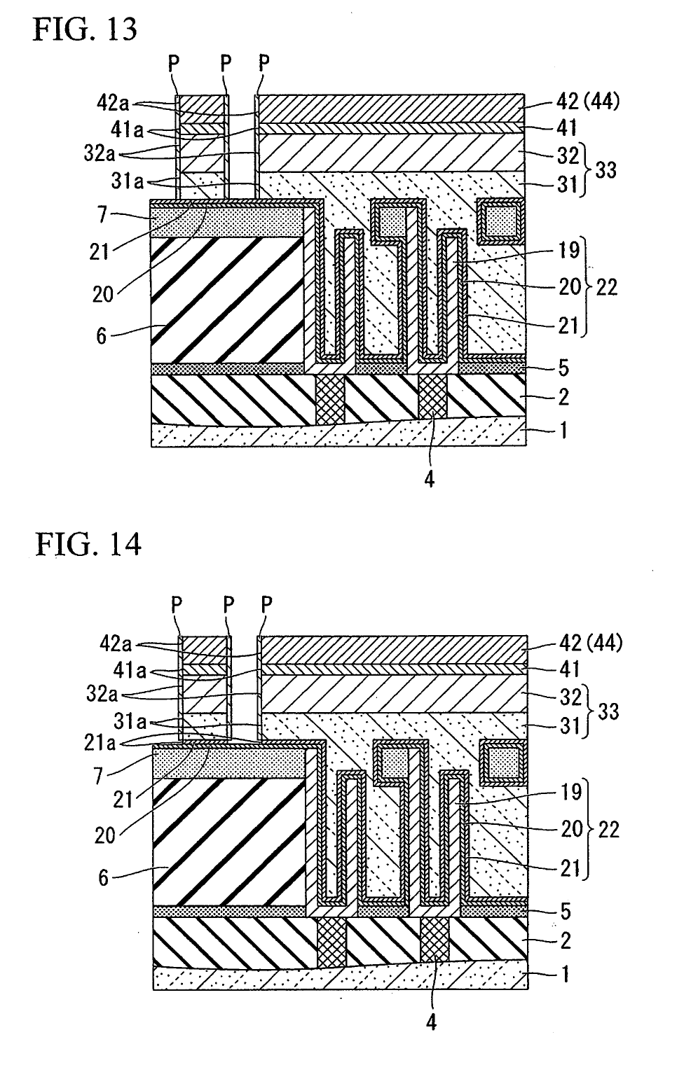

Then, the hard mask film 42 exposed through the hole 43a is dry etched using the photoresist film 43 as a mask, as shown in FIG. 11. Since the hard mask film 42 is made of Al₂O₃, a mixed gas including BCl₃ (with flow volume of 120 sccm) and Cl₂ (with flow volume of 80 sccm) is used as an etching gas.

Since the thickness of the hard mask film 42 is 35 nm, and the etching selectivity of Al₂O₃ to the photoresist film 43 is 1, the thickness of the photoresist film 43 after the etching is 315 nm (350 nm-35 nm). Due to the characteristics of the dry etching, an upper edge of photoresist film 43 is tapered.

The dry-etched photoresist film 43 attaches onto the side surface 43a of the photoresist film 43 as a polymer P. Since the hole 43a is formed down to a lower surface of the hard mask film 42, the polymer P also attaches onto the side surface 42a of the hard mask film 42. The polymer P prevents the side surface 42a of the hard mask film 42 from being side-etched.

Additionally, aluminum chloride, which is generated by etching the hard mask 42, is easy to sublime, and therefore hardly remains on the side surface 42a of the etched hard mask 42. For this reason, the aluminum chloride is not included in the polymer P. The polymer P can be fully removed by ashing or the like in the cleaning process without aluminum oxide generated from the aluminum chloride which remains.

Thus, the hard mask film 42 is patterned using the photoresist film 43 as a mask, and thereby a mask layer 44 including the photoresist film 43 and the hard mask film 42 deposited over the metal layer 32 is formed.

Then, in the first etching process, the peeling prevention film 41, the metal layer 32, and the embedded underlying layer (semiconductor layer) 31 covering the support layer 7 are sequentially dry etched while the photoresist film 43 is present, as shown in FIG. 12.

Since the peeling prevention film 41, the metal layer 32, and the embedded underlying layer 31 are made of SiO₂, W, and polysilicon, respectively, a mixed gas including SF₆ (with flow volume of 90 sccm) and Cl₂ (with flow volume of 100 sccm) or a mixed gas including CF₄ (with flow volume of 90 sccm) and Cl₂ (with flow volume of 100 sccm) is used as an etching gas.

Since the thicknesses of the peeling prevention film 41, the metal layer 32, and the embedded underlying layer 31 covering the support layer 7 are 50 nm, 10 nm, and 150 nm, respectively, and the etching selectivity of each of these films to the photoresist film 43 is 1, the thickness of the photoresist film 43 after the etching is 15 nm (350 nm-50 nm-100 nm-150 nm).

Since the entire surface of the photoresist film 43 is further etched during the dry etching, the dry-etched photo resist film 43 attaches onto side surfaces 41a, 32a, and 31a of the peeling prevention film 41, the metal layer 32, and the embedded underlying layer 31, respectively, as the polymer P. The polymer P prevents the peeling prevention film 41, the metal layer 32, and the embedded underlying layer 31 from being side-etched.

Additionally, silicon fluoride generated by etching the peeling prevention film 41 and the embedded underlying layer 31, and tungsten fluoride generated by etching the metal layer 32 are easy to sublime, and therefore hardly remains on the side surfaces 41a, 42a, and 31a thereof. For this reason, the silicon fluoride or the tungsten fluoride is not included in the polymer P. Therefore, the polymer P can be fully removed by ashing or the like in the cleaning process.

Then, in the photoresist-film removal process, the photoresist film 43 over the hard mask film 42 is removed by dry etching. A mixed gas including O₂ (with flow volume of 40 sccm) and Cl₂ (with flow volume of 60 sccm) or a mixed gas including O₄ (with flow volume of 40 sccm) and Ar (with flow volume of 60 sccm) is used as an etching gas. In this case, polymer is not newly generated by etching the photoresist film 43, and the existing polymer P still remain.

Although the thickness of the photoresist film 43 has been set to be larger than the minimum thickness by adding extra 15 nm to the minimum thickness calculated based on the etching selectivity of each film to be etched to the photoresist film 43, the thickness of the photoresist film 43 may be set identical to the minimum thickness. In this case, substantially the entire photoresist film 43 is removed after the first etching process, the photoresist-film removal process can be omitted.

Then, in the second etching process, the upper electrode (second electrode) 21 covering the support layer 7 is dry etched using the hard mask film 42 while substantially no photoresist film 43 is present, as shown in FIG. 14.

Since the upper electrode 21 covering the support layer 7 is made of TiN, a mixed gas including Cl₂ (with flow volume of 140 sccm) and Ar (with flow volume of 60 sccm) is used as an etching gas. Since the etching selectivity of the hard mask film 42 to the upper electrode 21 is 20, the thickness of the hard mask film 42 after the etching is 49.5 nm (50 nm-10/20 nm).

Since the photoresist film 43 is not present during the second etching, polymer is not newly generated during the second etching process, and the polymer P generated during the first etching process remains as it is. Therefore, the metal layer 32 and the embedded underlying layer 31 are prevented from being side etched.

Additionally, titanium chloride, which is generated by etching the upper electrode 21, is harder to sublime compared to the etching product generated by etching the first film in the first etching process. For this reason, the titanium chloride hardly remains on a side surface 21a of the upper electrode 21.

However, polymer is not generated during the second etching process. For this reason, the titanium chloride is not included in the polymer P. Therefore, the polymer P can be fully removed by ashing or the like in the cleaning process.

If the photoresist film 42 is present in the second etching process, titanium chloride generated by the second etching is included in the newly generated polymer P, thereby making it hard to remove the polymer P.

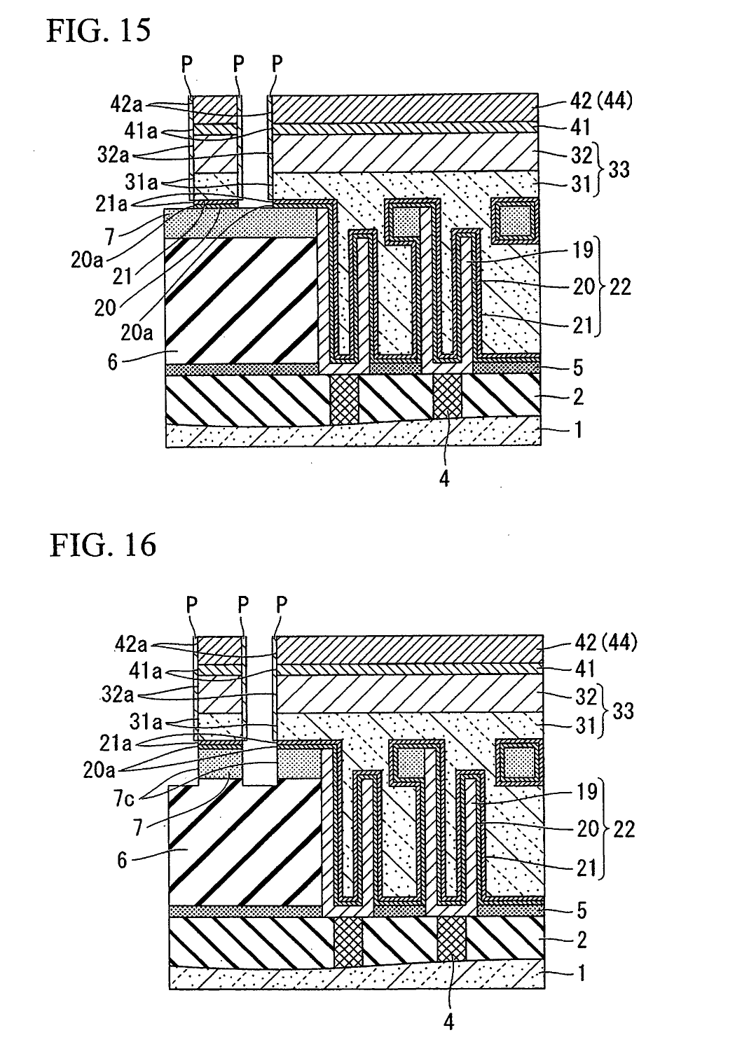

Then, the dielectric film 20 covering the support layer 7 is dry etched using the hard mask film 42 while substantially no photoresist film 43 is present, as shown in FIG. 15.

Since the dielectric film 20 is made of the multi-layered film including aluminum oxide and zirconium oxide, a mixed gas including BCl₃ (with flow volume of 120 sccm), Cl₂ (with flow volume of 80 sccm), and Ar (with flow volume of 60 sccm) is used as an etching gas. Since the etching selectivity of the hard mask film 42 to the dielectric film 20 is 0.2, the thickness of the hard mask film 42 after the etching is 14.5 nm (49.5 nm-7/0.2 nm).

Since substantially no photoresist film 43 is present during this etching, polymer is not newly generated, and the polymer P generated during the first etching process remains as it is. Therefore, the metal layer 32 and the embedded underlying layer 31 are prevented from being side etched.

Additionally, aluminum chloride and zirconium chloride, which are generated by etching the dielectric film 20, are easier to sublime than the aforementioned titanium chloride. For this reason, the etching products hardly remain on a side surface 20a of the dielectric film 20.

Further, polymer is not generated during the second etching process. For this reason, these etching products are not included in the polymer P. Therefore, the polymer P can be fully removed by ashing or the like in the cleaning process.

Then, the support layer 7 is dry etched using the hard mask film 42 while the photoresist film 43 is not present, as shown in FIG. 16. Since the support layer 7 is made of the silicon nitride (SiN), a mixed gas including SF₆ (with flow volume of 100 sccm) and Ar (with flow volume of 100 sccm) is used as an etching gas.

If the etching selectivity of the hard mask film 42 to the support layer 7 is assumed to be 20, the thickness of the hard mask film 42 after the etching is 9.5 nm (14.5 nm-100/20 nm).

Since the photoresist film 43 is not present during this etching, polymer is not newly generated, and the polymer P generated during the first etching process remains as it is. Therefore, the metal layer 32 and the embedded underlying layer 31 are prevented from being side etched.

Additionally, silicon fluoride, which is generated by etching the support layer 7, is easier to sublime than the aforementioned titanium chloride. For this reason, the etching product hardly remains on a side surface 7c of the support layer 7.

Further, polymer is not generated during the second etching process. For this reason, these etching products are not included in the polymer P. Therefore, the polymer P can be fully removed by ashing or the like in the cleaning process.

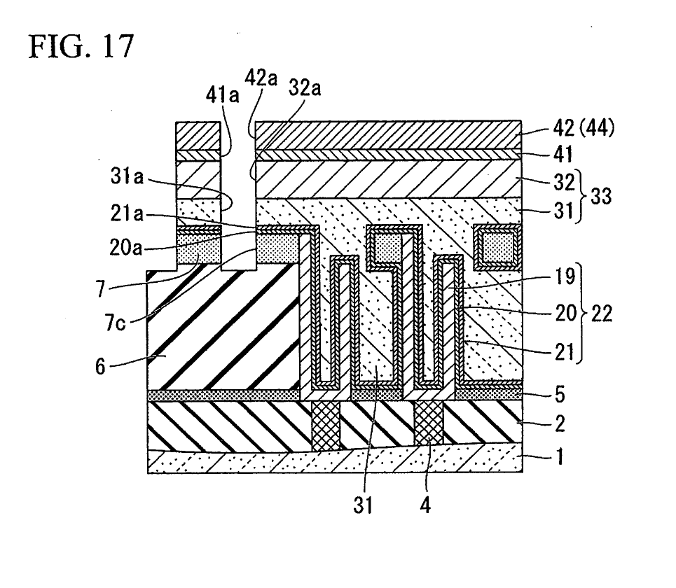

Then, in the cleaning process, the polymer P attached on the side surface of each layer is removed by ashing or the like, as shown in FIG. 17. The remaining hard mask film 42 is not reduced in thickness by the ashing.

If an etching product is included in the polymer P, the polymer P is hard to remove, and therefore a residue remains. The residue cannot be removed by the following wet cleaning process, and therefore causes erosion.

In the present embodiment, however, etching of a film causing generation of a high-volatile etching product is carried out while the photoresist film 43 is present. Additionally, etching of a film causing generation of a low-volatile etching product is carried out while substantially no photoresist film 43 is present. Therefore, an etching product is not included in the polymer P, thereby making it easier to remove the polymer P, and preventing a reside from remaining.

Then, a general manufacturing process is followed to form a semiconductor device including multiple memory cells each including the transistor and the cell capacitor.

As explained above, according to the method of the present embodiment, the first etching is carried out while the photoresist film 43 is present. During the first etching, the polymer P generated by decomposition of the photoresist film 43 attaches onto the side surfaces 32a and 31a of the metal layer 32 and the embedded underlying layer 31 to be etched in the first etching process. Therefore, the polymer P can prevent the metal film 32 and the embedded underlying layer 31 from being side etched during the first etching process.

Additionally, etching products are generated by etching the metal layer 32 and the embedded underlying layer 31. The generation of the etching products and the generation of the polymer P simultaneously proceed. However, the etching products hardly remain on the etching surfaces, and therefore is hardly included in the polymer P, thereby enabling easy removal of the polymer P in the removal process.

Further, the second etching process is carried out while substantially no photoresist film 43 is present. For this reason, the polymer P generated by decomposition of the photoresist film 43 does not attach onto the side surface 21a of the upper electrode 21 to be etched in the second etching process. Therefore, a film from which an etching product hardly volatilizes can be properly etched.

In other words, etching of the upper electrode 21 in the second etching process causes generation of a relatively low-volatile etching product. However, the polymer P is not generated in the second etching process. For this reason, the low-volatile etching product is not included in the polymer P. Therefore, removal of the polymer P in the cleaning process is easy.

Moreover, the entire photoresist film 43 or substantially the entire photoresist film 43 is removed after the first etching process, the polymer P, which is generated by decomposition of the photoresist film 43, is not generated in the second etching.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A method of manufacturing a semiconductor device, comprising:
performing a first etching process that etches a layer using a resist mask and a hard mask, the resist mask covering the hard mask, and the hard mask covering the layer; and
performing a second etching process that etches the layer using the hard mask, substantially in the absence of the resist mask.

2. The method according to claim 1, further comprising:
removing, before the second etching process, a remaining portion of the resist mask if the remaining portion resides after the first etching process.

3. The method according to claim 1, further comprising:
forming, before the first etching process, the resist mask having a thickness being such that the resist mask is substantially removed after the first etching process.

4. The method according to claim 1, wherein the layer has a multi-layered structure.

5. The method according to claim 4, wherein
the multi-layered structure comprises first and second films,
the first film covers the second film,
the first film is etched by the first etching process,
the second film is etched by the second etching process,
the first film comprises a first substance having a first volatility, and
the second film comprises a second substance having a second volatility smaller than the first volatility.

6. The method according to claim 5, wherein
the first film comprises at least one of tungsten and polysilicon, and
the second film comprises titanium nitride.

7. A method of manufacturing a semiconductor device, comprising:
forming a memory cell structure;
forming a semiconductor layer covering the memory cell structure;
forming a metal layer covering the semiconductor layer;
forming a hard mask covering the metal layer;
forming a resist mask covering the hard mask;
performing a first etching process that etches the semiconductor layer and the metal layer using the resist mask and the hard mask; and
performing a second etching process that etches the memory cell structure using the hard mask, the second etching process being performed in the absence of the resist mask.

8. The method according to claim 7, further comprising:
removing, before the second etching process, a remaining portion of the resist mask if the remaining portion resides after the first etching process.

9. The method according to claim 7, further comprising:
forming, before the first etching process, the resist mask having a thickness being such that the resist mask is substantially removed after the first etching process.

10. The method according to claim 7, wherein
the semiconductor layer comprises a first substance having a first volatility,
the metal layer comprises a second substance having a second volatility,
the memory cell structure comprises a third substance having a third volatility, and
the third volatility is smaller than the first volatility and the second volatility.

11. The method according to claim 10, wherein
the first substance is polysilicon,
the second substance is tungsten, and
the third substance is titanium nitride.

12. A method of manufacturing a semiconductor device, comprising:
etching a first film using a first mask and a second mask different from the first mask, the first mask covering the second mask, and the second mask covering the first film, the first film covering a second film, and at least a part of the first mask being etched by etching the first film;
removing a remaining portion of the first mask if the remaining portion resides after etching the first film; and
etching the second film using the second mask.

13. The method according to claim 12, further comprising:
forming a barrier film covering etching side surfaces of the first and second masks and the first film while the first mask is etched, forming the barrier film being performed by attaching a substance on the etching side surfaces, the substance being supplied by etching the first mask,
wherein the barrier film prevents the second mask and the first film from being side-etched during etching the first film and etching the second film, and
the method further comprises:
removing the barrier film after etching the second film.

14. The method according to claim 12, wherein
the first film comprises a first substance having a first volatility, and
the second film comprises a second substance having a second volatility smaller than the first volatility.

15. The method according to claim 12, wherein
the first mask comprises a resist film, and
the second mask comprises an aluminum oxide film.

16. The method according to claim 12, wherein
the first film comprises at least one of tungsten and polysilicon, and
the second film comprises titanium nitride.

17. The method according to claim 12, wherein
the first mask, the second mask, the first film, and the second film have first to fourth thicknesses, respectively, and
the first thickness is equal to or greater than a sum of first to third products, the first product is obtained by multiplying the second thickness by a first selectivity of the second mask to the first mask, the second product is obtained by multiplying the third thickness by a second selectivity of the first film to the first mask, and the third product is obtained by multiplying the fourth thickness by a third selectivity of the second film to the first mask.

18. The method according to claim 12, wherein etching the first film and etching the second film are performed by inductively-coupled-plasma reactive-ion-etching.

19. The method according to claim 13, wherein removing the barrier film is performed by ashing.

20. The method according to claim 12, further comprising:
patterning the first and second masks before etching the first film.
